(19) United States
(12) Patent Application Publication
(10) Pub. No.: US 2012/0242412 A1
(43) Pub. Date: Sep. 27, 2012

(54) Auto Bias

(76) Inventor: Peter Fletcher-Haynes, Denver, CO (US)

(21) Appl. No.: 13/430,524

(22) Filed: Mar. 26, 2012

Related U.S. Application Data
(60) Provisional application No. 61/467,891, filed on Mar. 25, 2011.

(51) Int. Cl. H03F 3/04; H03G 3/20

(52) U.S. Cl. 330/296; 330/127

(57) ABSTRACT

An auto bias system, device and/or method for automatically controlling the bias or quiescent point of at least one vacuum tube including separating bias current flow from signal current flow for controlling the bias/quiescent point by algorithmically adjusting the grid bias voltage whilst monitoring the cathode current to establish the correct bias current.

### BACKGROUND

Vacuum tube or linear MOSFET (semiconductor) amplifiers generally require some form of ‘biasing’ whether the device is used in the power stages or not. Biasing is also generally required regardless of the ‘Class’ of the amplifier, in the case of vacuum tubes this could be class A, A1, A2, B, AB1, AB2, C or others. In the case of the output devices correct biasing is a factor in the safe and optimal operation/performance of the devices and the amplifier for the particular class.

The bias which sets the operating point is analogous to the quiescent point in semiconductors. It should be noted that the ‘bias voltage’ can be either positive or negative depending upon the device type being controlled, though this is normally negative with vacuum tubes.

Generally the bias arrangement falls into two distinct methods; cathode (self bias) or fixed bias, both of which can be adjustable. Generally amplifiers that provide for the capability of adjustment use the fixed bias method which employs expensive rheostats or switched power resistors which are required specifically to handle the cathode/source currents.

Fixed bias tube amplifiers generally require a negative voltage with respect to the cathode. These are often loosely regulated, using a simple zener circuit, and adjusted via a trim potentiometer. Bias may then be adjusted to either set the correct cathode current or a known grid bias voltage for the device. (In the case of Class C the bias is set to cut-off.) The latter, grid voltage setting method, can be problematic since it can cause wide variations in cathode current because of device to device variations, and variations in Anode voltage and load, for example, since the actual true bias point (cathode current) is unknown.

In the case of adjusting the fixed bias by measuring cathode current a small ohmic value resistor can be placed in the cathode which has little or no effect on tube/device operation. Ohms law is then applied to calculate the cathode current by measuring the voltage drop across the cathode resistor, for convenience a 1 Ohm or 10 Ohm resistor is often used, yielding 1 mV/mA or 10 mV/mA respectively. In addition, for simplicity and or cost constraints, often the adjustable bias is applied to all of the output tubes via one overall adjustment; this assumes that the devices are relatively well matched and will have the same or similar quiescent current which often is not the case. When ‘separate’ bias adjustment is available on these amplifiers adjusting bias generally requires an ‘iterative’ adjustment since as current changes, anode voltage changes and the ‘other’ tube will draw more or less current as a consequence.

In both the musical instrument market and HIFI market both customer types often like to change tubes to obtain a different voicing of the amplifier ‘tube rolling’ often with different tube types, for example substituting a EL34 with a 6L6. A significant number of the owners of these amplifiers do not possess the skills to either simply replace tubes or tube roll without technical assistance to adjust for correct biasing which may require component changes and the use of test equipment.

Since in many cases, the amplifiers do not have regulated plate voltage supplies, biasing can change significantly with plate voltage variations, most often caused by line voltage fluctuations or simply a high or low line supply. Causing the amplifier to be either under or over biased may affect either or both performance and tube life.

The tubes, over time, change in performance and may require periodic bias adjustments or at least checking. Further, these amplifiers may want the tubes to be matched for optimum performance and to ensure plate current balance between tubes. This is exacerbated when tubes are paralleled to increase output power.

Although alternative auto bias arrangements do exist, they are in limited use and are generally restrictive or inflexible. The use of ‘indicators’ for bias point is more prevalent; however, they still require the user to manually adjust the bias point.

### BRIEF DESCRIPTION OF DRAWINGS

FIG. 1 is an exemplar circuit.

FIG. 2, which includes sub-part FIGS. 2A, 2B and 2C, is a method hereof.

FIG. 3 is an exemplar Interrupt Service Routine (ISR) for an Analog to Digital Converter (ADC).

FIG. 4 is an exemplar ISR for a Comparator.

FIG. 5 is an exemplar ISR for a Modulo.

FIG. 6 is an exemplar ISR for a Computer Operating Properly (COP).

FIG. 7 is an exemplar ISR for Key Press.

FIG. 8 is an exemplar ISR for a Timer.

### AUTO BIAS CONTROLLER BRIEF DESCRIPTION OF OPERATION AND CURRENT IMPLEMENTATIONS

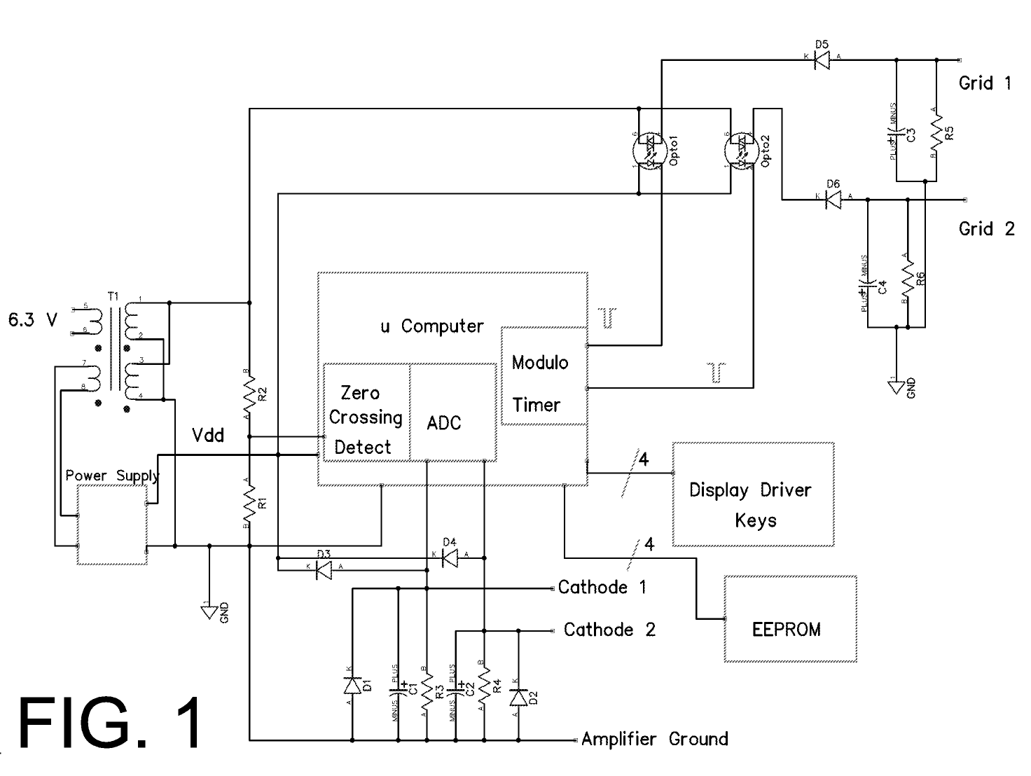

Auto bias systems hereof typically utilize a highly configurable programmable general purpose micro-controller or computer. (An exemplar circuit is shown in FIG. 1.) This may allow for auto bias systems or modules or circuits hereof to be retrofitted to existing amplifiers or incorporated into new production amplifiers with or without fixed bias. Auto bias circuits hereof may operate from only the amplifiers 6.3 Volt filament supply, however, other ‘sources’ of power could alternatively be used. The on-board power supply may generate the required voltages to power the on-board computer as well as generating the bias supply voltages.

An auto bias module hereof may have one, two, or more, identical independent bias control circuits. The computer measures the voltage drop across an on board cathode resistor. Based on the programmable ‘target’ cathode current, which may be predetermined, the computer can algorithmically change the applied grid bias voltage to ‘optimally’ bias the tubes/devices to the target cathode current/s.

A large number of methodologies could be applied to regulate or control cathode/source current, in some cases, the negative grid/gate bias voltage. Several power supply topologies were explored and prototyped including but not limited to adjustable switching mode, linear, cascaded switching with linear. One implementation, for controllability, ease of use and low cost was a triac controlled supply.

A micro-computer to be used herein could be one of thousands of different types; however, they are generally typified by utilizing relatively low voltage DC supplies. The inputs and outputs of these devices are generally limited in current and voltage handling. The controller is desired for capability to regulate/adjust the bias voltage which is typically many times greater than the limits of the device and in the case of a negative bias voltage, typically the wrong polarity. The micro-computer (or external comparator) in many implementations hereof may be set to detect the zero crossing of the AC line, which gates accurate timers to provide the trigger pulse current for optically isolated triacs during the correct conduction quadrant, which cause the triacs to avalanche. Such a method is a conduction controlled half wave rectifier. The triac will charge a ‘reservoir’ capacitor; the voltage across the capacitor is determined by the conduction phase angle. Using ‘optically’ coupled triacs can ‘isolate’ the micro-computer from the high voltage bias supply or supplies. Other optically coupled devices could be employed to provide not only isolation but a regulation method for the bias supply/s. One method that was built and operated was a DTA (Digital to Analog converter) utilizing the ‘reference’ voltage on a linear high voltage regulator, switching in resistors via an optically isolated FET's. Other methods could alternatively be employed.

The optically isolated triacs used were actually designed to control larger high current/voltages devices. To minimize danger, if the triacs are triggered in the wrong quadrant typically caused by line spikes, a protection diode is placed in series with the triac, preventing reverse polarity to the reservoir capacitors. (Most triacs are multi-quadrant). To prevent non conduction as the ac line reduces in amplitude (sine wave) the triacs are ‘loaded’ with a resistor to meet minimum hold current requirements.

An auto bias controller hereof may utilize an on board cathode resistor, its value chosen to enable an ADC (analog to digital converter) to directly convert the voltage drop without the need to amplify or condition the voltage. The ADC's utilized to convert the voltage to a digital value are in some implementations on board to the computer and have a range of 0 to 5 Volts with 10 bit resolution (0-1023). However, other resolutions and voltage range or external devices could be used as well as could instrumentation amplifiers to ‘adjust’ or condition the measurement ranges. To accommodate a wide possible range of devices to be measured for cathode/source current a 20 Ohm resistor was chosen. This could be ‘scaled’ to change the characteristics. To reduce ‘noise’ in the system and to reduce cathode current variations caused by the signal applied to the device/tube the cathode resistors can be bypassed. Other methods could be employed to ‘detect’ the voltage, for example comparators. The voltage measured across the cathode resistors is directly proportional to cathode current.

It should be noted that in the case of Triode devices the cathode current is essentially the same as the anode current. In the case of Tetrodes, Pentodes and other multiple grid devices the cathode current is the sum of the Plate/Anode current plus the screen grid current, although this has little consequence in the performance of the system. Programmatically the computer may have parameters set to allow for a different voltage drop according to the cathode resistor value selected.

Although a direct correlation exists between the control grid set point, quiescent point, and the cathode current given a known plate voltage for a specific device. A generalized correlation does not exist between a control grid voltage and cathode current for all devices. The specific cathode current for a known grid and plate voltage can be obtained from the characteristics provided by the tube manufacturer. Therefore, the grid bias controller may be adapted to ‘target’ a required cathode current, set point; by adjusting the grid voltage until this criterion is met.

In its simplest form the bias controller hereof continuously adjusts the grid bias voltage/s to keep the cathode/source voltage/s constant maintaining a specific quiescent point. In practice the computer can adjust the grid voltage almost instantaneously as the current changes in the cathode. However, the cathode current typically does change, albeit that the cathode resistor is bypassed, coincident with a delta change of grid signal. If this occurs the controller introduces ‘noise’ or artifacts into the system and is essentially providing a form of feedback that is typically unwanted. A compromise may be reached such that the time constant of the system only reacts to relatively slow moving changes in cathode current. The controller may be adapted to accomplish this through various algorithms implemented in the computer as well as the cathode bypass capacitors.

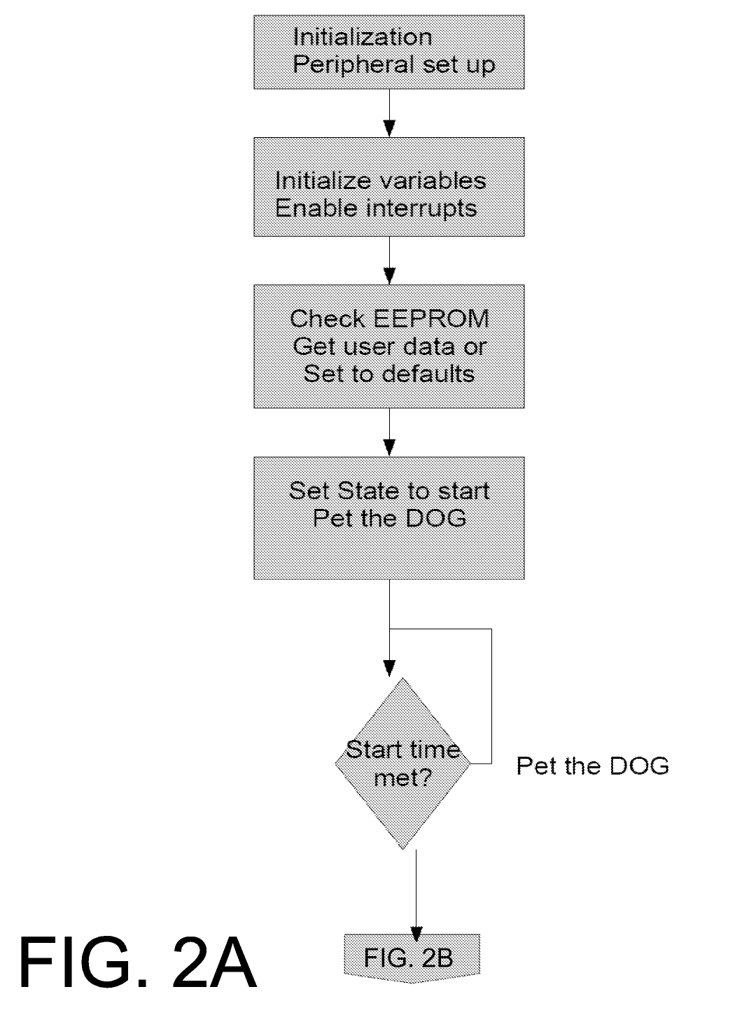

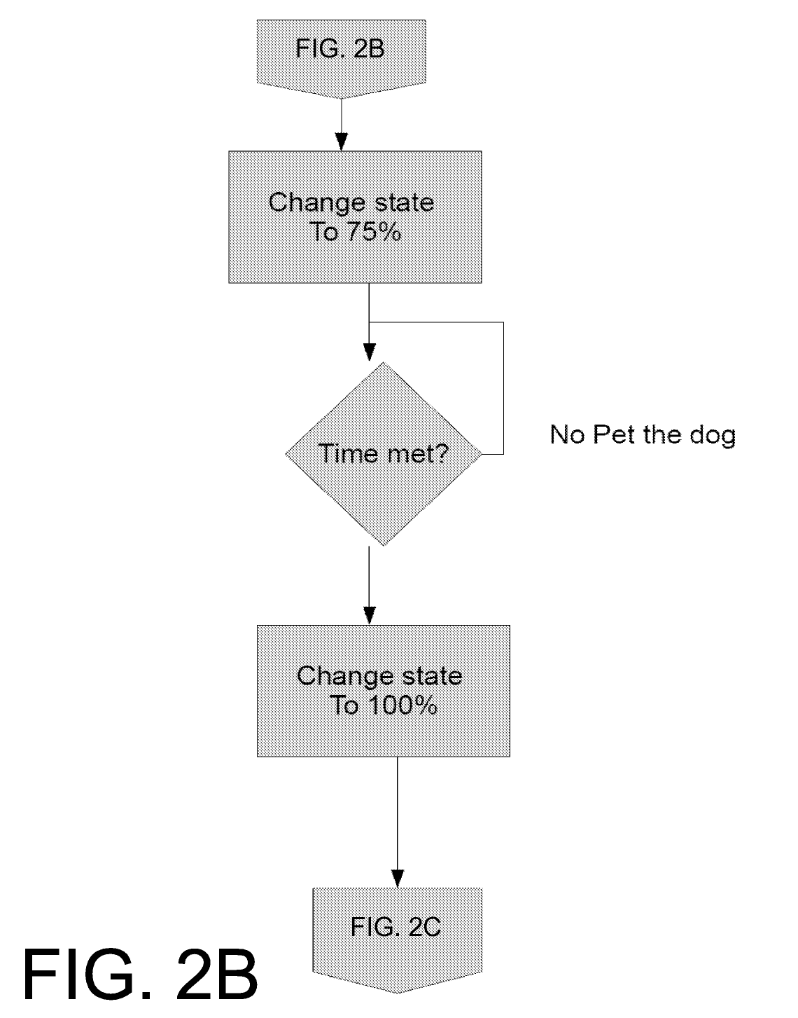

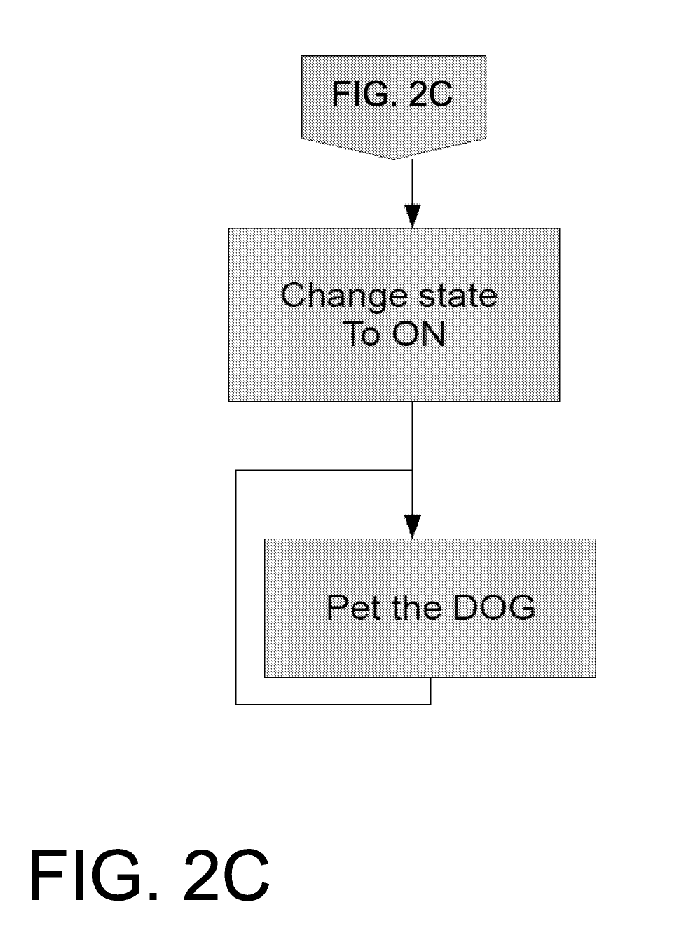

By way of further algorithmic description one may look at the various conditions occurring during normal and abnormal operation. When the system, amplifier and controller are first turned on, in case of vacuum tubes, the cathode is cold, and until the cathode increases in temperature, in the case heated cathode tubes, no plate current flows. As the temperature increases the anode current should increase assuming that the grids controlling the tube/s are not causing cut off. Since some tubes could take as long as 60 seconds to begin conduction the bias controller may algorithmically set the grid voltage to the highest level essentially forcing tube cut-off until operational temperature is reached. (A typical, generalized flow methodology is shown, for example, in FIG. 2, sub-parts 2A, 2B and 2C, starting with initialization.)

The controller hereof would generally automatically start immediately once power is applied and drive the grid voltage to maximum after the ‘initialization’ phase of the computer, time of which is measured in microseconds. The computer then waits, with maximum grid voltage applied for turn-off, until a pre-determined time period, which would typically be programmable, is met; typically e.g., 45-60 seconds. The controller would then assume that the vacuum tubes have reached sufficient operating temperature to begin the process of ‘setting’ stable cathode currents.

In this implementation the controller (micro-computer) starts the next phase of operation/state and changes the grid voltage (increment or decrement to settle on the target current). In the case of vacuum tubes, the grid voltage is made more positive i.e. reduces the magnitude of the negative grid voltage. Since this is an important time period the controller will typically have been programmed to sample the cathode voltage drop relatively quickly, however, to ensure that it does not ‘hunt’ around changes in cathode current caused by any ripple on the bias supply, it samples at a rate longer than the time constant set by the reservoir capacitor, line frequency and bleed resistor. In addition, the timers, which are used to ‘trigger’ the triacs, have high resolution. The mechanism is to sense the zero crossing point of the AC supply, adjust a modulo register value to ‘set’ the trigger point which pulse triggers the triac/s; essentially (PWM) Pulse Width Modulation. Since these modulo counters have high resolution, during this phase/state the incremental values used to adjust/set the modulo counter/s may be high.

Because the data can be used later, the controller saves the modulo counts which set a specific trigger point on the triacs, which is proportional to grid voltage, that controls the cathode current. A target of for example, 75% of the true target cathode current may be used, although other values maybe appropriate and could be used, so that in ‘other’ phases the counter value can be used for a start point for control purposes. Once a predetermined time period has elapsed adjusting to the example 75% current level, by incrementing or decrementing the modulo counter, the controller may change state.

In this next state, the target current may be finely adjusted and under or over shoot may thus be minimized. This may be accomplished by reducing the modulo counter increment size value and slowing the cathode sampling period. After a predetermined settling time the controller may change state again to a normal running state, which may reduce the sampling period further as well as may reduce the modulo adjustment increments. This slows the ‘response’ of the system to avoid any hunting.

Averaging the ADC samples to reduce noise impacts may be available programmatically.

Based, on ‘guard’ bands parametrically set, the micro computer may adjust the size of the increments and decrements to the modulo counters applicable to the specific state. This can allow for ‘quick’ changes or smaller changes to grid voltage depending on how far the current is from nominal.

As mentioned before the ‘value’ of the modulo counter that ‘caused’ a specific cathode current was previously stored, which can be used if during operation the plate current drops dramatically to effect a fast safe ‘recovery’.

A dramatic/drastic drop in plate current is often caused by removal of the plate voltage. This is generally caused when the amplifier is placed into user standby, since some amps use this method of standby control. The controller hereof typically has no direct plate voltage sensing, although this can easily be added, so during this event the controller will try to reduce grid voltage to increase current flow. If then the plate voltage is restored the grid voltage could be at a relatively small negative value and heavy plate current could occur. To mitigate this event the controller may restore the control grid voltage, using the previously stored modulo value, that caused the example 75% plate current and recovers target current adjustment from there, it also may increase the ‘step’ size adjustments to the modulo counters for faster control.

The architecture of the software/firmware in the microcontroller may be of a state machine with full asynchronous interrupts for zero AC line crossing, ADC conversions, pulse modulo counters, COP (computer operating properly) and other events including switch presses, although polling methods could also/alternatively be used. Other architectures known to those in this field could be used to implement the control mechanisms.

As the microcomputer moves through states, from start up to normal running state the system may move from a ‘tightly’ coupled feedback mechanism toward a ‘loosely coupled’ feed forward mechanism, with occasional corrective feedback. In this way the ‘time constants’ of the system requirement can be maintained. Numerous states or single states could be utilized to accomplish this goal. System adjustments are not necessarily made if the target current is within programmable guard bands.

One implementation of a system hereof utilizes seven (7) segment LED displays and push buttons to ‘set’ user configurations, provide data information and status. However, the system could be pre-configured for specific applications with no or little information provided back to the user and could employ none or single indication devices. Various methods could be used to input data and output data for the user. LCD displays, graphical as well as text, rotary switches, membrane switches etc as well as communications interfaces to other computers or devices.

In a preferred implementation only two ‘control’ loops are implemented, however, one or many could alternatively be used; for example, a single channel or eight channel controller.

As line voltages fluctuate which can cause plate voltage variations the controller may adjust automatically the grid voltage to compensate. This compensation may be also applied automatically as the tubes change characteristics over time.

Often, amplifiers are operated in single tube Class A configurations as well as parallel tube class A (single ended) topologies and an amplifier could have many tubes in parallel. In common class AB (push pull) amplifiers it is typically a minimum requirement to have two tubes (these could be in a single envelope), but once again, to increase power handling multiple tubes are often placed in parallel. One implementation of this controller ‘targets’ the cathode current of one tube. The user has the option of telling the controller that more than one tube is in parallel, as by way of a non-limiting example, four (4) tubes may be employed. The user in such an example may specify the number of tubes each channel of the controller is to use and calculates the ‘total’ current being monitored by the single cathode resistor. Following through this example, the target current could be set to 45 mA and a tube number of 4 entered. The target current would then be displayed as 45 mA, the number of tubes displayed as “4.” The ‘actual’ current for each cathode could then also be displayed and in this case should be 180 mA when ‘on target’. In a push pull topology with 4 parallel tubes in each leg of the push pull, the two Cathode current indicators would indicate 180 mA each when ‘on target’.

In vacuum tube output stages, the harmonics produced may be different than similar topologies using semiconductors. This is a major contributor to the ‘vacuum tube sound’ as a discrete and often desirable alternative. Often to reduce or enhance these harmonics users will under or over bias the tubes, changing the operating point of the tube and hence the harmonics produced. One implementation of the controller allows the user to select from ‘nominal’, ‘low’ or ‘high’ bias. A microcontroller hereof would, if nominal is selected, control the cathode current to the ‘target’ current. If, however, the user selects either a low or a high bias, the controller would subtract or add to the nominal target current, as for an example, 10% may be added to or subtracted from the nominal target current respectively. Other variations of this theme, percentage and/or alternative or additional levels of low and/or high could be incorporated.

In one implementation, the on-board ADC has a range of 0-5V in 1024 monotonic steps, with multiple tubes being set for specific tube current targets where it is possible to exceed the ADC range and or damage the ADC. The ADC inputs may be clamped to the computers supply voltage to prevent damage and the computer software would typically limit target and tube counts to be within range specifications automatically adjusting maximum available currents or values.

To minimize the necessity of non-standard resistors and or slow floating point mathematics whose routines are often non-re-enterable the software may utilize ‘offset’ and look up tables using integer mathematics. A general purpose computer may perform ‘adds’ and shifts relatively quickly. An actual calculated current per ADC bit in a system hereof was 0.00024438 Amps or approximately 244 uA. The approximation of 250 uA may be used herefor to divide the ADC counts by 4 (actually two shifts right) to yield milli0Amps (mA's), however it can be seen that as the ADC counts increase so does the accumulative error. The software may utilize a ‘look up’ table to add in an offset adjustment to correct for the error based on the magnitude of the ADC value. The high low functionality for target current may similarly be obtained by using a pre-calculated integer table rounded to the nearest ADC count so floating point use is not necessary and ‘rounding’ errors can be nearly eliminated. One implementation may keep the ‘target’ current to an approximate +/−1 mA range, but other ranges and accuracies could be alternatively be accommodated.

The system may be equipped with non-volatile memory to try to ensure that the correct ‘settings’ are used to bias the amplifier, hence retaining the information after power down or failure. When the system starts up again the information may be read from the non-volatile memory and thus used for ‘configuration’ settings. To try to ensure that information is not corrupted the system may employ one or several ‘defensive’ mechanisms. Although non-volatile memory can take many forms and can easily be used, in one implementation, the information is stored in EEPROM (electrically erasable programmable memory). In such a case, the data has a guaranteed greater than 100 year's retention capability. As mentioned, the system may have several mechanisms to try to prevent ‘bad’ data, which could accidentally set the bias control system to operate in a way that could damage the tubes and or amplifier. The computer may utilize a high priority interrupt COP (computer operating properly) mechanism. A ‘timeout’ could be used to trigger a computer restart automatically if not reset periodically during operation (petting the watch dog). If ‘runaway’ occurs then the computer could be forced to restart from a known good state by restarting which also sets the grids drive voltage to maximum turning the tubes off. The ‘user’ data may be ‘packed’ into a single byte, although many bytes could be used, the complementary data may be stored in the next byte. In addition, preceding the data stored may be disposed two bytes of ‘unique’ data. When the computer starts the data packet, all four bytes, may be read and if the unique data does not match or the 2^{nd} information byte does not match the compliment of the parametric data the ‘read’ may be established as a fail. A ‘safe’ minimum current and one (1) tube may be selected or established as the default. This would typically happen the very first time the computer turns on since sensible data may not have been programmed into memory. In addition, ‘security’ may be used to protect from erroneous writes. A ‘write’ enable command can be set to be sent to the EEPROM, once programmed, the data would then be read and validated and the write protection command sent to the EEPROM preventing spurious writes. The same mechanisms can be used once the user has entered their own parameters, such that when the controller is turned on again the correct amplifier drive settings would be used. In this implementation the ‘normal’, ‘low’ and ‘high’ bias may be established to always reset to ‘normal’ after power failure or turn off.

The controller may be configurable through parameters, component selection and jumpers to be able to derive grid voltages (positive or negative) from, for example, +/−5 to over +/−200 Volts. In an implementation the ‘cathode’ resistor value, and hence current measured can be set, via an internal parameter, to 20 Ohms. However, it could easily be ‘user’ configurable if more or less current measurement is required/desired. If the existing system needs to be changed by a user, an additional cathode resistor placed in series or parallel with the internal one could be used. The user or computer would then simply have to calculate the ‘actual’ current and set and read the displays accordingly. If for example a parallel 20 Ohm resistor is used target currents could be halved to compensate and ‘actual’ currents multiplied by 2.

Since not in all cases would there necessarily be suitable voltages available to the controller from the amplifier to be controlled, the controller may be adapted to utilize a mains transformer. However, it is not always convenient to supply the controller with ‘line voltage levels’. Many output tubes use 6.3 Volts for the filament supply. Here then, the controller's power transformer could use a ‘standard’ low power filament transformer but in reverse. The filament transformer can then provide either 0-120 or 0-240 volts (if used in parallel or series) for the grid supply and 6.3 volts AC for the controller's computer supply. A low drop out regulator would typically be used for the digital power supply so that ‘margin’ can be maintained for adequate regulation.

In many amplifier configurations the output tubes will be relatively closely matched. The controller, since it has multiple channel capabilities, can mitigate to some degree what might otherwise be considered a near necessity for close matching since each tube can be automatically individually biased.

‘Musical instrument’ amplifiers have often been designed to provide relatively high power audio outputs. In some situations, this may be too much power, especially for studio, practice or small venues. A bias controller hereof can provide an opportunity to ‘down size’ the amplifier. If the ‘large’ amplifier has for example, 6 tubes in the output stage it would be possible to ‘set the tube’ quantity to 4 or even 2 and after turning the amplifier off removing several tubes. The controller can then be utilized to keep the amplifier, with the reduced tube set, in correct bias.

Although primarily intended to be a ‘control’ mechanism, a bias controller hereof can be used successfully to simply ‘monitor’. In such an operational mode, which can occur, for example, before full control implementation, the grid control circuits may not be connected to the amplifier to be monitored and the amplifiers ‘internal’ bias mechanism would then be used. The controller hereof may then be placed in the cathodes to monitor the amplifiers cathode current/s. This mode may provide for ensuring an existing amplifier is operating correctly before coupling in the control circuits and establishing a base line cathode current for automatic operation.

Controllers hereof may utilize, as previously mentioned, a 6.3V filament voltage for the tube heaters (2 wires). In addition, a common ground may be connected as the reference. The on-board cathode resistor may then be connected to the tube cathode. In the case of a retrofit, if the amplifier is cathode biased, the cathode resistor in the amplifier may be removed and replaced with the controllers. In the case of a fixed bias amplifier the cathode may be disconnected from ground and connected to the internal cathode resistor instead. The grid leak/grid stopper resistor in the case of a cathode biased amplifier may either be removed or connection to ground is removed and connected to the grid control resistor on board the controller. In case of a fixed bias amplifier the grid resistor may be separated from the existing bias supply and connected to the controller instead. For ‘monitoring’ only, only 4 wires may be used to monitor the amplifier (single tube amp) or 5 wires in the case of 2 tube amp. If control is desired an additional one wire per tube may be used. For safety and convenience the impedance of the grid supply may be limited by on-board resistors. These can be bypassed or additional resistors placed in series.

The controller may ‘soft’ start the vacuum tubes, prolonging the life of the amplifier and tubes by gradually increasing plate current at start up.

The controller may allow the amplifier to be placed into ‘standby’, in which case, the controller can be adapted to simply increase the magnitude of the grid voltage to or near cut-off or control the plate voltage directly. The ‘toggle’ switches may change back and forth from ‘run’ to standby. Placing the amplifier into standby when not being used may prolong the life of the vacuum tubes.

An adjustable cathode mechanism could also/alternatively be used for automatic biasing of cathode biased amplifiers, if a change to fixed bias is not appropriate or desired. In this case computer controlled ‘shunting’ of the cathode resistor may accomplish the same or near the same level of control as this bias control method.

One implementation may provide for setting up the controller with a target cathode current. The grid voltage may then be automatically adjusted to derive the correct bias current, the grid voltage not necessarily being known. The user would typically then be provided with or extrapolated from supplier's amplifier specifications the optimal bias current for each tube type. It would be possible to ‘select’ an actual tube type and configuration to accomplish the same goal, in which case the controller would select the ‘correct’ bias point automatically.

Monitoring of plate voltage is possible by the addition of another ADC or similar device. The controller, if monitoring the plate voltage, could easily calculate the ‘actual’ power being dissipated by the output device/s as well as determine if plate voltage is present which simplifies power fail recovery whatsoever caused.

A bias controller, in one or more of these implementations, may indicate the status of the controller by means of indicators. Specifically, actual current, state, adjustment rate, if current is low or high or on target. Others could be incorporated.

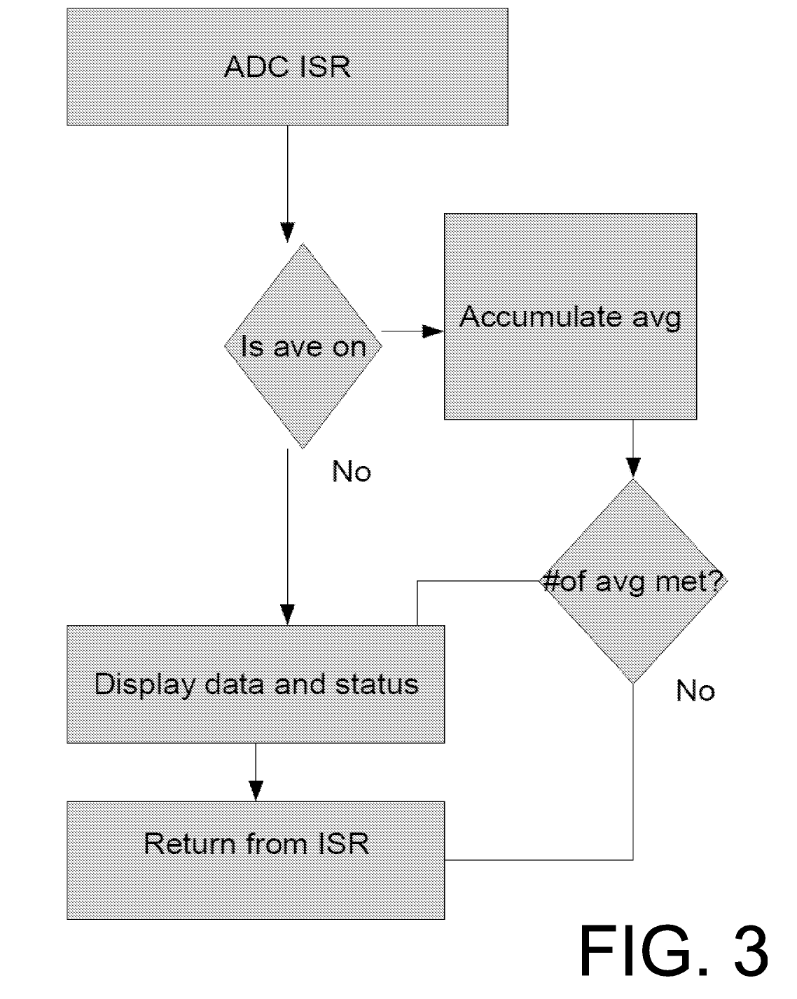

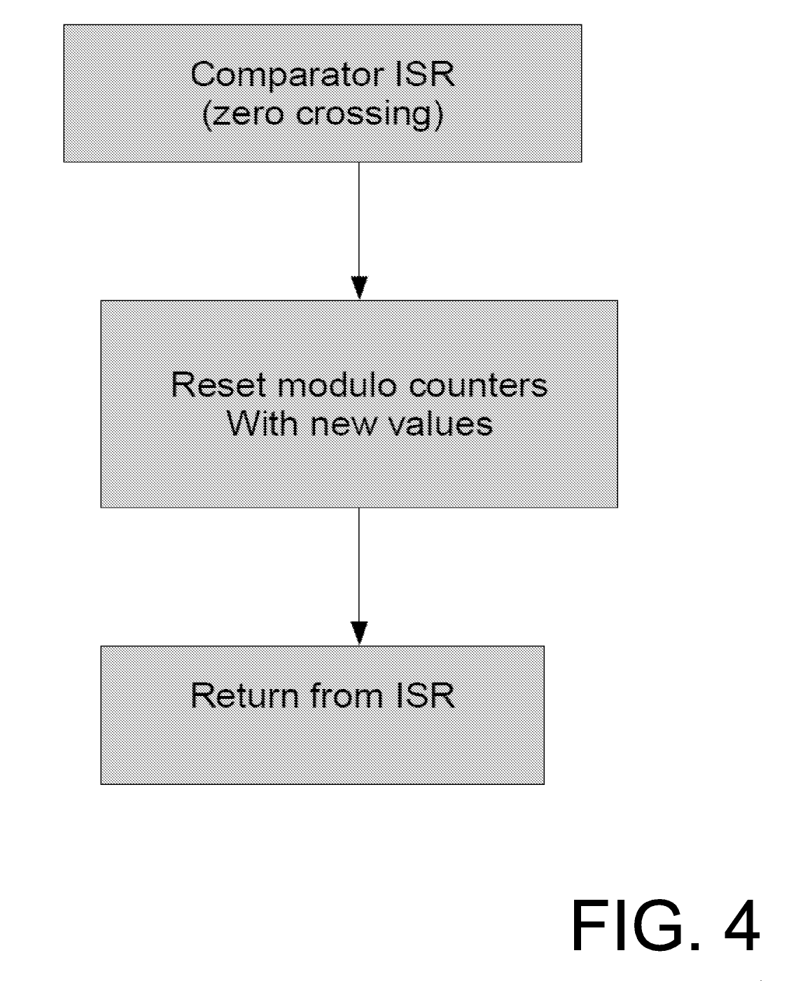

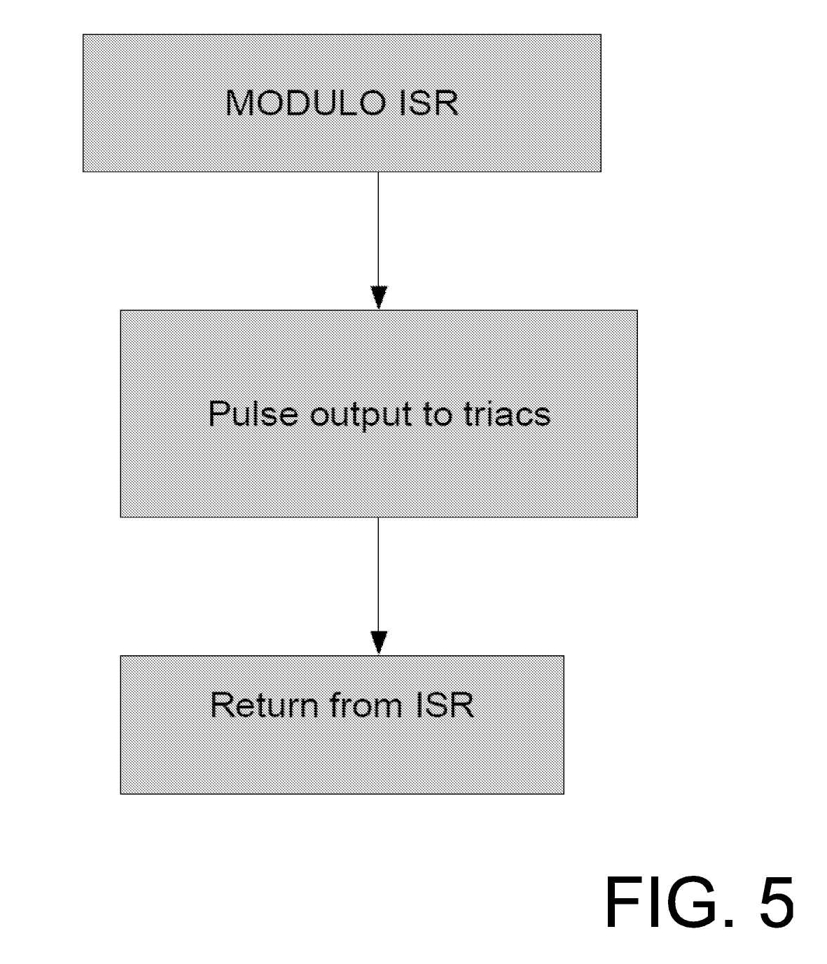

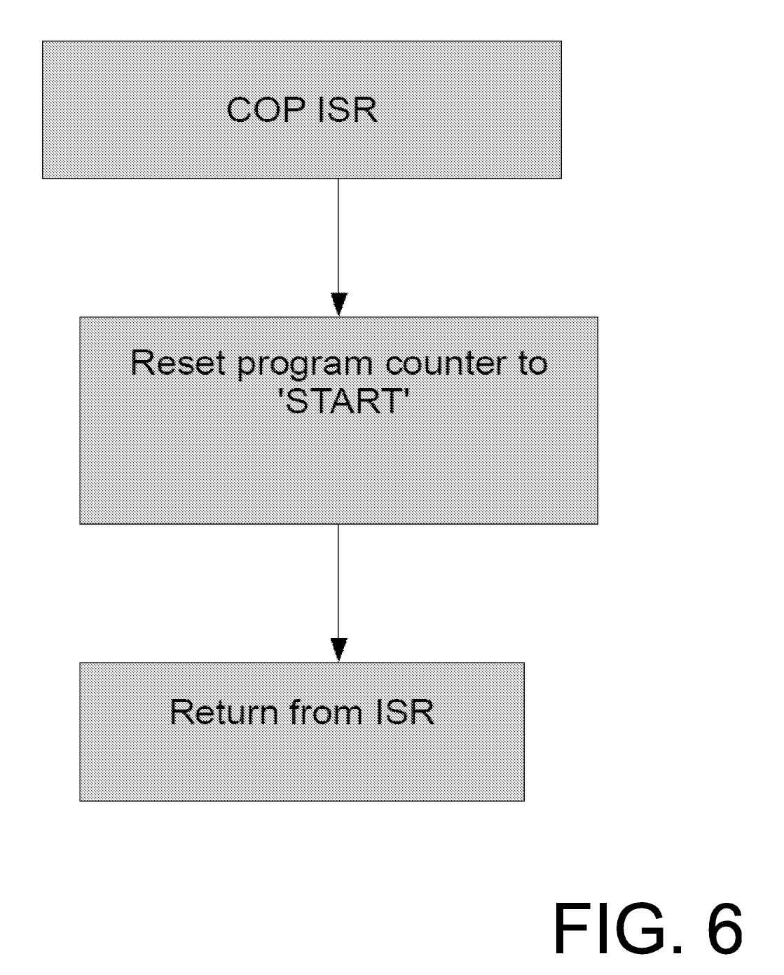

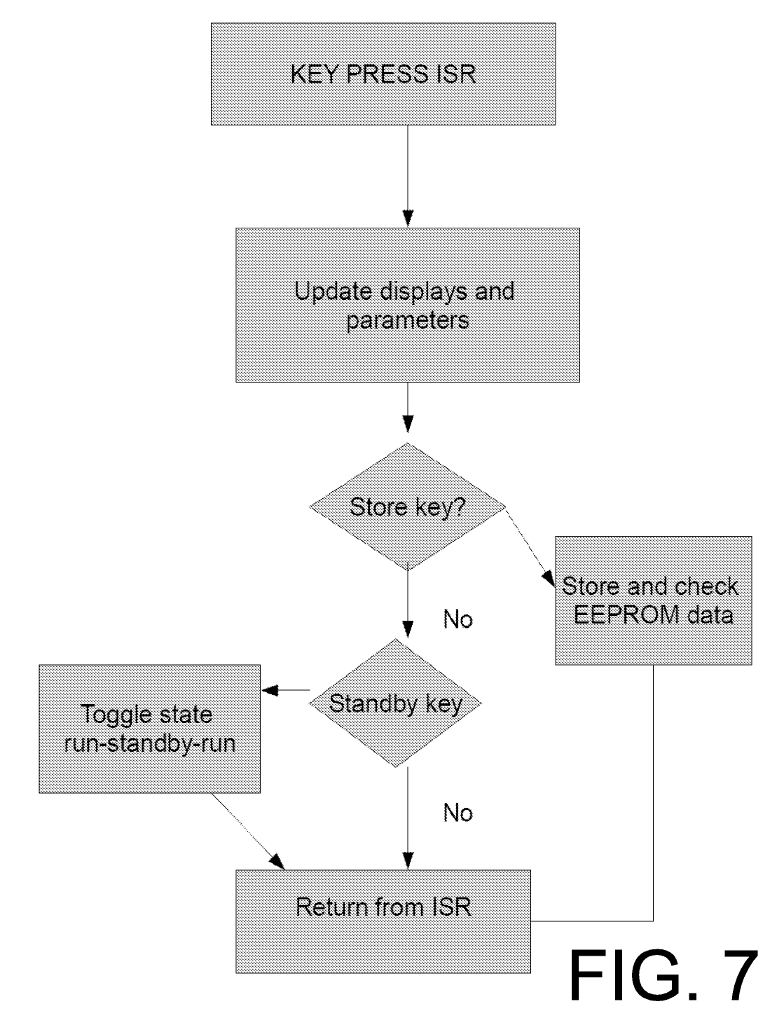

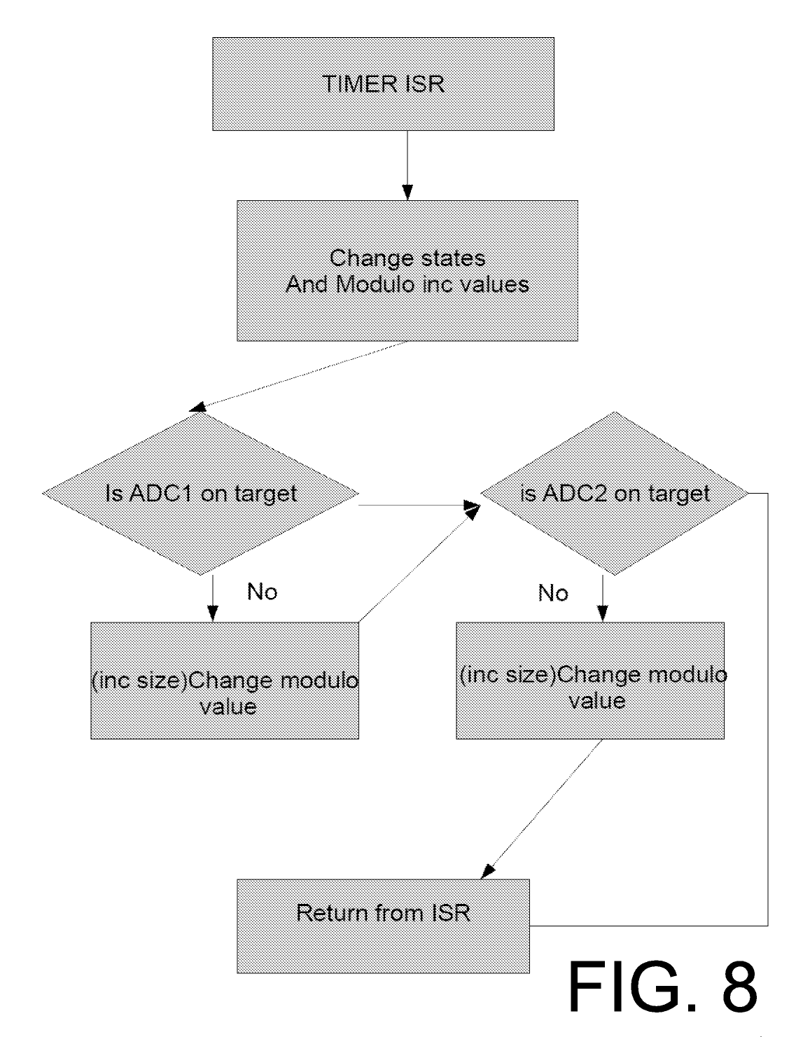

FIGS. 3-8 provide various interrupt service routines which may be used herewith.

Some alternative elements hereof may include one or more of:

A method of or apparatus or system for directly and automatically controlling the correct bias point of vacuum tubes or semiconductor devices by adjusting the control grid or gate of a semiconductor device.

A method of or apparatus or system for allowing multiple tubes or devices to be controlled simultaneously.

A method of or apparatus or system for enabling a ‘soft start’ the tube or semiconductor device by controlling the magnitude of the grid or gate voltage.

A method of or apparatus or system for minimizing the necessity of closely matched devices in plural device configurations by controlling the bias point for each device.

method of or apparatus or system for retrofitting or incorporating an auto bias controller hereof into an amplifier using ‘other’ methods to control biasing.

A method of or apparatus or system for swapping tube types/devices into an amplifier without the necessity of re-biasing.

A method of or apparatus or system for enabling ‘automatic’ recovery from lost plate voltage once plate voltage has been restored.

A method of or apparatus or system for automatically adjusting for the correct bias point if fluctuations or low or high line voltage conditions occur.

A method of or apparatus or system for changing the characteristic harmonics of an amplifier by automatically biasing the amplifier nominally, high or low, ‘voice the amplifier’.

A method of or apparatus or system for changing the power of the amplifier by biasing the amplifier automatically if devices or tubes are removed or added.

A method of or apparatus or system for biasing an amplifier automatically regardless of amplifier class.

A method of or apparatus or system for obtaining status indications of current state, actual currents, and failure or adjustment conditions.

A method of or apparatus or system for keeping the amplifier biased within a +/−1 mA target current accuracy or better.

A method of or apparatus or system for placing the amplifier into standby by driving the control grid to ‘cut-off’.

Although the present developments have been described with reference to preferred implementations, workers skilled in the art will recognize that changes may be made in form and detail without departing from the spirit and scope of the development described herein.

1-23. (canceled)

24. A method for controlling a bias condition of an electronic device of an amplifier, the method comprising:
determining a bias condition of an electronic device of the amplifier; and
adjusting a control condition of the electronic device based upon the bias condition to adjust the bias condition toward a target bias condition.

25. The method according to claim 24 wherein the electronic device comprises a vacuum tube, the bias condition comprises a bias cathode current and the control condition comprises a grid voltage.

26. The method according to claim 25 wherein the grid voltage is derived from a heater supply of the vacuum tube.

27. The method according to claim 26 wherein a supply voltage for at least one controller is derived from the heater supply of the vacuum tube.

28. The method according to claim 25 further comprising placing the vacuum tube in a standby condition by applying a grid voltage adapted to at least substantially turn off cathode current flow through the vacuum tube.

29. The method according to claim 24 wherein the electronic device comprises a MOSFET, the bias condition comprises a MOSFET current flow and the control condition comprises a gate voltage.

30. The method according to claim 24 wherein the electronic device comprises at least one of the group comprising: a vacuum tube, a transistor, a FET, a MOSFET, a bi-polar transistor.

31. The method according to claim 24 further comprising replacing the electronic device with a second electronic device, determining a second bias condition of the second electronic device and adjusting the control condition based upon the second bias condition to adjust the second bias condition toward the target bias condition.

32. The method according to claim 24 further comprising:
determining a second bias condition of a second electronic device of the amplifier; and
adjusting a second control condition of the second electronic device based upon the second bias condition to adjust second the bias condition toward a second target bias condition.

33. The method according to claim 24 wherein the target bias condition comprises a variation from an optimal bias condition of the electronic device.

34. The method according to claim 33 wherein the variation comprises a fixed or variable deviation.

35. The method according to claim 24 wherein the target bias condition comprises a user-adjustable bias condition.

36. The method according to claim 35 further comprising providing the bias condition as a user-displayable output.

37. A method of adjusting a bias for an amplifier comprising:
provide an output voltage having a first voltage level, the first voltage level adapted to drive a grid voltage to prevent current flow in at least one amplifier element;
adjust the output voltage to provide a second voltage level having a lesser magnitude than the first voltage level, the second output voltage level adapted to drive a grid voltage to bias the at least one amplifier element for operation.

38. The method according to claim 37 wherein the at least one amplifier element comprises at least one vacuum tube.

39. The method according to claim 37 wherein the second output voltage level is provided by decrementing the first output voltage level.

40. The method according to claim 39 wherein the second output voltage level is provided by decrementing the first output voltage level by at least one predetermined voltage level.

41. The method according to claim 37 wherein the second output voltage level is adjusted based upon a cathode current of the at least one amplifier element.

42. The method according to claim 41 wherein a controller, upon being turned on, provides the first voltage level as the output voltage until (i) a programmed time or (ii) a sampling of a cathode current under a reduced grid voltage has determined the at least one amplifier element has warmed up sufficiently to allow plate current adjustment to target a bias current.

43. The method according to claim 37 further comprising determining a bias condition of the at least one amplifier element; and adjusting a control condition of the at least one amplifier element based upon the bias condition to adjust the bias condition toward a target bias condition
